(19) United States
(12) Patent Application Publication
(10) Pub. No.: US 2022/0408049 A1
(43) Pub. Date: Dec. 22, 2022

(54) MULTI-LAYER STACKED CAMERA-IMAGE-SENSOR CIRCUIT

(71) Applicant: Meta Platforms Technologies, LLC, Menlo Park, CA (US)

(72) Inventors: Ziyun Li, Bellevue, WA (US); Barbara De Salvo, Belmont, CA (US); Xinqiao Liu, Medina, WA (US); Lyle David Bainbridge, San Francisco, CA (US); Andrew Samuel Berkovich, Sammamish, WA (US); Syed Shakib Sarwar, Bellevue, WA (US); Song Chen, Redmond, WA (US); Tsung-Hsun Tsai, Redmond, WA (US)

(21) Appl. No.: 17/728,880

(22) Filed: Apr. 25, 2022

Related U.S. Application Data
(60) Provisional application No. 63/213,580, filed on Jun. 22, 2021.

(51) Int. Cl. H04N 5/369; H01L 27/146

(52) U.S. Cl. CPC H04N 5/379; H01L 27/14634; H01L 27/14636; H04N 5/37452

(57) ABSTRACT

A stacked camera-image-sensor circuit may include (i) a first layer that includes a plurality of image sensing elements, (ii) a second layer that includes components that interface with the image sensing elements, and (iii) at least one additional layer that includes image-processing components. Various other methods, systems, and computer-readable media are also disclosed.

### CROSS REFERENCE TO RELATED APPLICATION

This application claims the benefit of U.S. Provisional Application No. 63/213,580, filed 22 Jun. 2021, the disclosures of each of which are incorporated, in their entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is a block diagram of an exemplary multi-layer stacked camera-image-sensor circuit.

FIG. 2 is a flow diagram of an exemplary method performed by a multi-layer stacked camera-image-sensor circuit.

FIG. 3 is an illustration of an exemplary multi-layer stacked camera-image-sensor circuit.

FIG. 4 is an illustration of an exemplary intelligent image sensing and computing platform in which light data is multiplexed from one layer to another layer.

FIG. 5 is an illustration of exemplary augmented-reality glasses that may be used in connection with embodiments of this disclosure.

FIG. 6 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

Features from any of the embodiments described herein may be used in combination with one another in accordance with the general principles described herein. These and other embodiments, features, and advantages will be more fully understood upon reading the following detailed description in conjunction with the accompanying drawings and claims.

### DETAILED DESCRIPTION OF EXEMPLARY EMBODIMENTS

The present disclosure is generally directed to a multi-layer stacked camera-image-sensor circuit that includes digital pixel sensors. Some specific embodiments may implement dense micro through-silicon vias and/or different technology nodes to optimize (e.g., reduce) size constraints in the form-factor of current digital pixel sensor (DPS) architecture.

In the past, digital pixel sensors included two layers: a top layer of photodiodes and a bottom layer that included analog-to-digital converters (ADCs) and static random access memory (SRAM) for each photodiode. In the second layer of these traditional chips, ADCs could be manufactured on sub-22-nm silicon layers, but SRAM memory cells (which are physically larger) could not. In the current digital pixel architecture, the digital pixel sensor is partitioned into two layers: the photo diode layer on layer one (e.g., 65 nm in width) and the application-specific integrated circuit (ASIC) on layer two (e.g., 45 nm in width). These two layers may be densely connected via a hybrid bond for each pixel on layer one. During each image capture, the ADCs on the ASIC layer perform data conversion (converting detected analog light values to digital values) and store the converted value in the 10-bit SRAM cells tightly coupled with the pixel ADC on layer two. Accordingly, because of the large size requirements of the SRAM cells on the second layer, further reducing photodiode density on the DPS has become extremely difficult.

In contrast, the embodiments described herein may separate the ADCs and SRAM memory cells onto different layers in a multi-layer approach that may use three or more layers. In this multi-layer approach, the first layer may include photodiodes, the second layer may include ADCs (e.g., one ADC for each photodiode in layer one), and the third layer may include the SRAM memory (or other type of memory), with each ADC having one corresponding SRAM memory cell. The ADC may communicate with the SRAM memory on the third layer using micro through-silicon vias (uTSVs). These uTSVs may allow for ultra-fast, high-bandwidth data transfers between the second and third layers. By allowing the ADCs to be manufactured on a sub-22-nm layer, the photodiodes may similarly be placed in smaller, sub-22-nm form factors, while the larger SRAM memory cells may be spread out over the third layer, as they no longer need to share space with the ADCs. By providing increased photodiode density in this manner, the embodiments herein may provide stacked camera-image-sensor circuits with increased dynamic range, increased operational speed, and/or decreased power requirements.

In some embodiments, the systems described herein may improve the functioning of a computing device by enabling the computing device to process image data more quickly, effectively, and/or efficiently. Additionally, the systems described herein may improve the field of image processing by decreasing the form factor and/or increasing the efficiency of DPS chips.

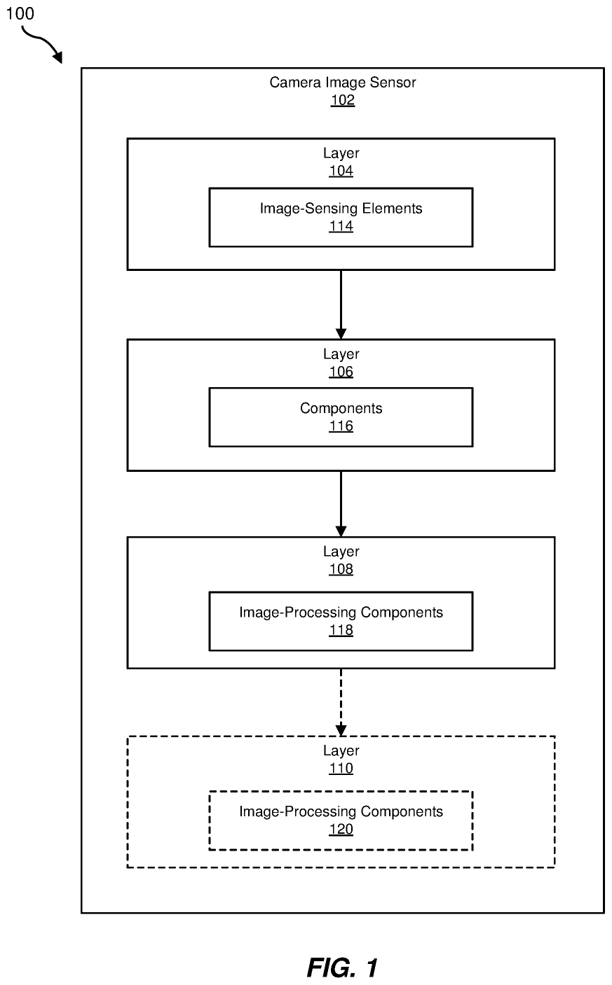

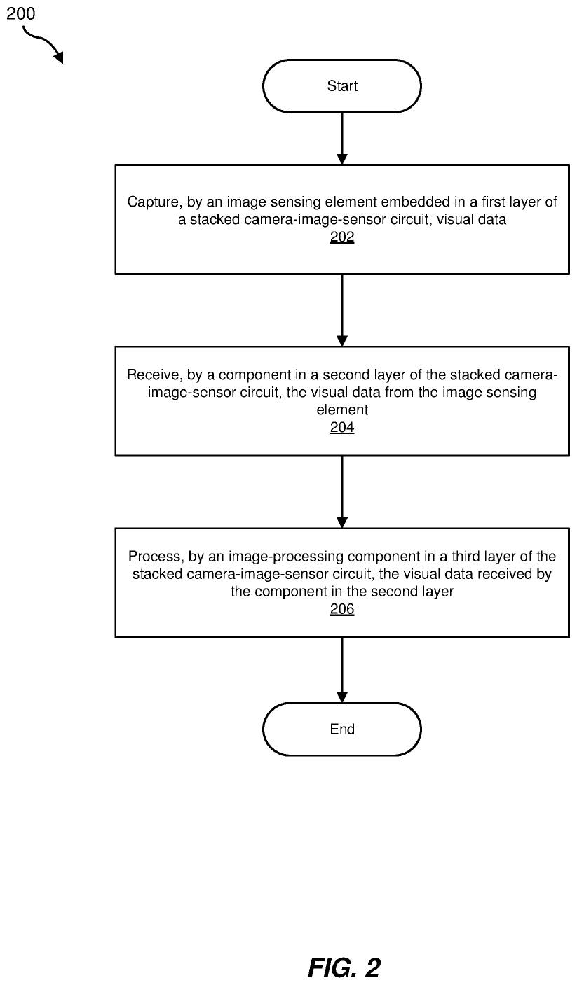

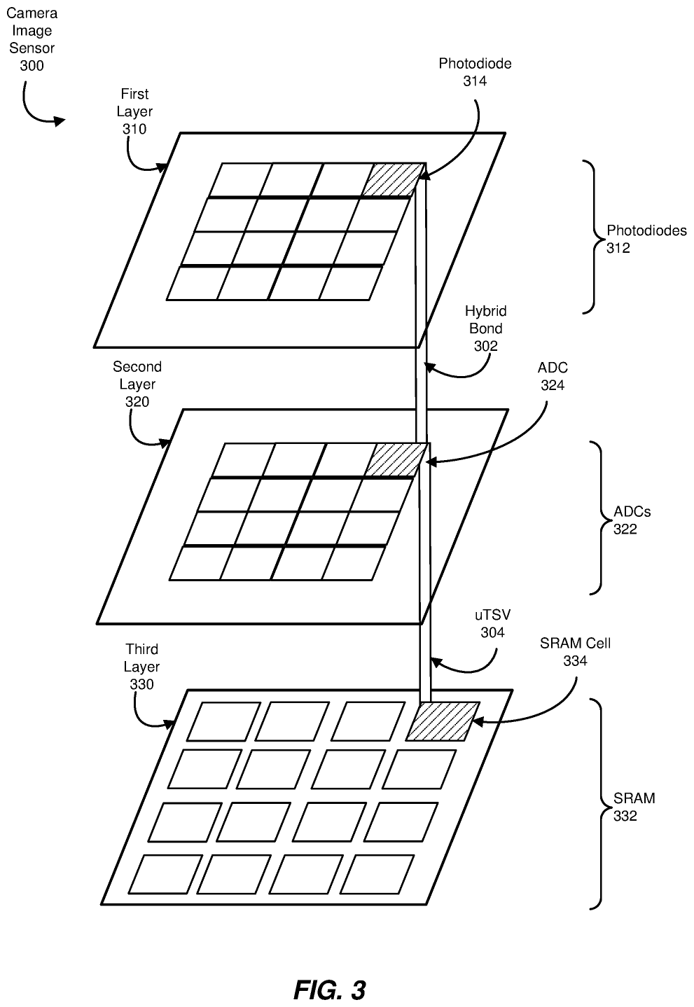

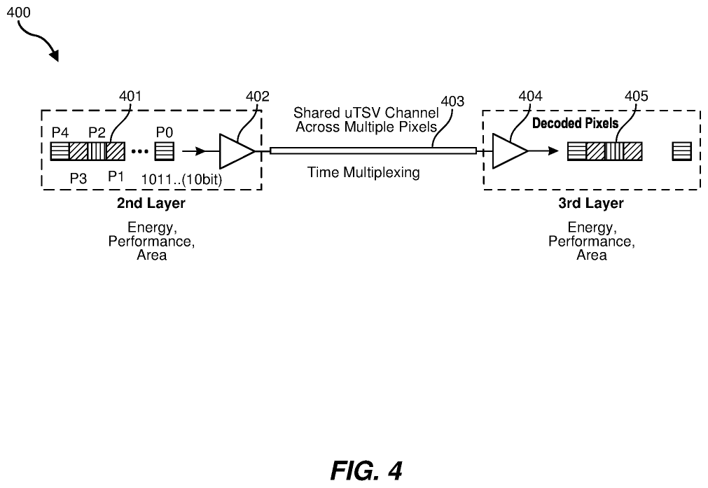

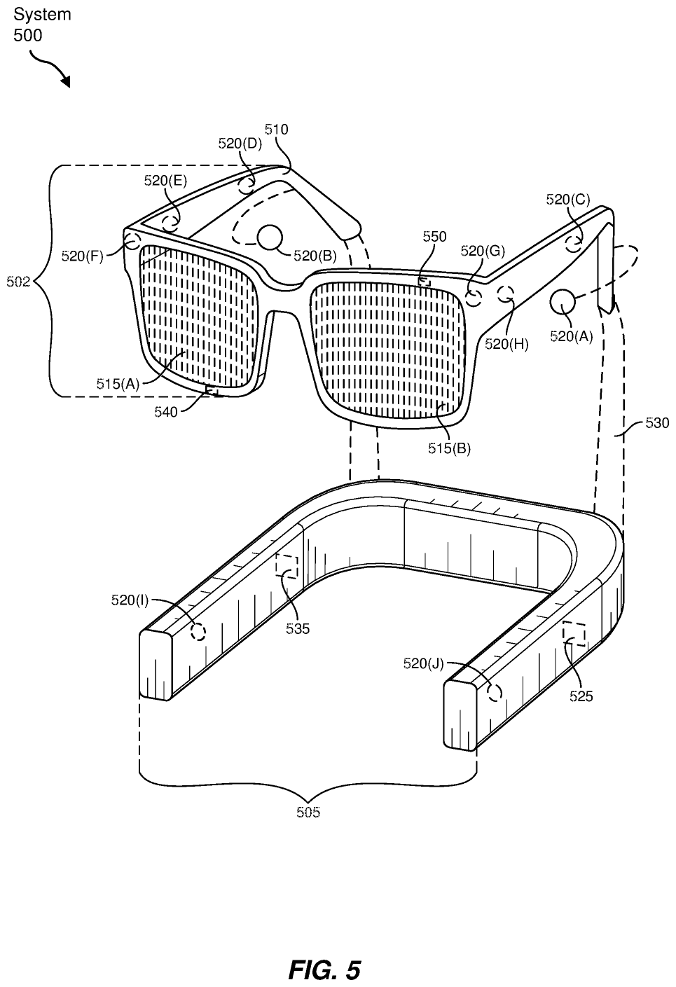

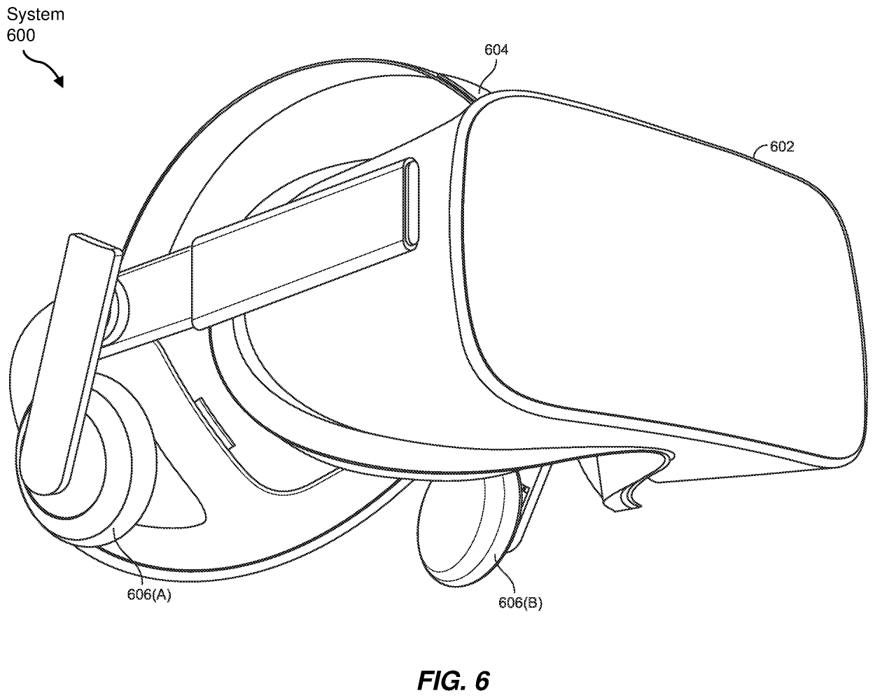

The following will provide detailed descriptions of exemplary multi-layer stacked camera-image-sensor circuits in connection with FIGS. 1 and 3. Detailed descriptions of methods for processing images via a multi-layer stacked camera-image-sensor circuit will be provided with reference to FIG. 2. A detailed description of an exemplary intelligent image sensing and computing platform in which light data is multiplexed from one layer to another layer will be provided in connection with FIG. 4. Additionally, detailed descriptions of exemplary augmented and/or virtual reality embodiments will be provided in connection with FIGS. 5 and 6.

In some embodiments, the systems described herein may be a multi-layer stacked camera-image-sensor circuit with multiple specialized layers. FIG. 1 is a block diagram of an exemplary camera image sensor 100. In one embodiment, camera image sensor 100 may include layers 104, 106, and/or 108. In some embodiments, camera image sensor 100 may include additional layers. In some examples, layer 104 may be configured with image-sensing elements 114. In one example, image-sensing elements 114 may include photodiodes. In one embodiment, layer 106 may include components 116. In some examples, components 116 may transfer data between elements or components on layer 104 and elements or components on layer 108. In one example, components 116 may include ADCs.

In some embodiments, layer 108 may include image-processing components 118. Image-processing components may represent various types of hardware components including memory (e.g., SRAM) and/or computing chips (e.g., machine learning chips). In one embodiment, image-processing components 118 may process image data captured by image-sensing elements 114. In some embodiments, camera image sensor 100 may include additional layers with additional specialized elements or components not found on layers 104, 106, and/or 108 that communicate with one or more elements or components on other layers. For example, camera image sensor 100 may include a layer 110 with image-processing components 120 such as machine learning chips that communicate with SRAM on layer 108. In some embodiments, layer 110 may communicate with layer 108 via uTSVs.

FIG. 2 is a flow diagram of an exemplary method 200 for capturing and processing images via a stacked camera-image-sensor circuit with specialized layers. In some examples, at step 202, the systems described herein may capture, by an image sensing element embedded in a first layer of a stacked camera-image-sensor circuit, visual data. For example, image-sensing elements 114 on layer 104 of camera image sensor 100 may capture visual data.

The systems described herein may capture a variety of types of visual data in a variety of contexts. For example, the systems described herein may capture a single frame of image data. In some examples, the systems described herein may repeatedly capture frames of image data (e.g., as a streaming video). In some embodiments, the systems described herein may capture image data as part of an augmented reality or virtual reality system, as described in greater detail in connection with FIGS. 5 and 6.

At step 204, the systems described herein may receive, by a component in a second layer of the stacked camera-image-sensor circuit, the visual data from the image sensing element. For example, components 116 on layer 106 may receive the visual data from image-sensing elements 114.

The systems described herein may receive data from a variety of types of components. In some embodiments, the component(s) may be one or more ADCs. In some examples, the ADCs may receive data from the first layer, convert the data from analog to digital, and send the converted data to the third layer.

At step 206, the systems described herein may process, by an image-processing component in a third layer of the stacked camera-image-sensor circuit, the visual data received by the component in the second layer. For example, image-processing components 118 on layer 108 may process the visual data received by components 116 in layer 106.

The systems described herein may process the visual data in a variety of ways. In some embodiments, the systems described herein may store the visual data in memory on the third layer. Additionally or alternatively, the systems described herein may process the data via data processing hardware on the third layer. In one embodiment, the systems described herein may store the visual data in memory on the third layer and then process the data on at least one additional layer (e.g., a fourth layer such as layer 110 in FIG. 1, a fifth layer, etc.).

In one embodiment, a stacked camera-image-sensor circuit with a digital pixel sensor may include a circuit with three specialized layers. In this embodiment, the photodiodes may be disposed on the first layer, while the ASIC layer is split onto two layers. As such, the ADCs may be placed on the second layer, and the SRAM memory cells for each pixel may be placed on the third layer. For example, as illustrated in FIG. 3, a camera image sensor 300 may include multiple component parts. Each of these component parts may form an intelligent image sensing and computing platform that is more compact, more energy efficient, and provides faster computing power than previous DPS imaging systems. In some embodiments, camera image sensor 300 may include a first layer 310 that may be referred to herein as an image sensing layer or photodiode layer. In some embodiments, first layer 310 may include multiple different photodiodes 314. Examples of photodiodes 314 may include, without limitation, charge-coupled devices (CCDs), active-pixel sensors (complementary metal-oxide-semiconductor (CMOS) sensors), or other similar image sensing devices. These photodiodes 314 may be configured to detect incoming light when exposed to light via an open shutter. First layer 310 may include substantially any number or type of photodiodes 314. Moreover, these photodiodes 314 may be arranged in substantially any shape or type of layout.

In some embodiments, first layer 310 may be connected to a second layer 320 that includes one or more image processing components configured to process the light detected by the photodiodes 314. The image processing components of the second layer 320 may include, but are not limited to, analog-to-digital converters (e.g. ADCs 322). In some embodiments, each photodiode 312 may have its own corresponding ADC (e.g., ADC 324) on second layer 320. In some examples, ADCs 322 may be configured to convert detected light (in an analog value) to a digital value that can be stored in memory and/or transmitted to an external data store (e.g., a cloud data store). In some examples, ADCs 322 of second layer 320 may be connected to photodiodes 314 via hybrid bonds (e.g., via copper connections). For example, ADC 324 may be connected to photodiode 312 via a hybrid bond 302.

Additionally, in some examples, ADCs 322 may be connected to elements on a third layer 330 via one or more uTSVs. The term “uTSVs” may generally refer to any vertical electrical connections that pass directly through silicon (or other substrate) between layers of an integrated circuit. In some examples, uTSVs may be much smaller than standard through-silicon vias (TSVs) and may have a much smaller footprint on a processing chip. Indeed, each use of a TSV on a processing chip may result in an area on that chip that is a “keep-out zone” or “dead zone” on which other electronic components (e.g., transistors, capacitors, diodes, etc.) or traces may not be placed. In some cases, TSVs may result in large dead zones on processing chips, reducing the processing power and efficiency of those chips. Micro TSVs, however, have much smaller dead zones and, as such, many more can be implemented on a chip such as a machine learning processor or other type of image processor.

In some embodiments, third layer 330 of may include one or more processing chips in such as hardware processing components, encoders, transmitters (or transceivers), and/or other image processing components. In one embodiment, third layer 330 may include memory, such as SRAM 332. In some examples, SRAM 332 may store a frame buffer. In some embodiments, each ADC may be coupled with one or more dedicated uTSVs from second layer 320 to third layer 330. These uTSVs (or other types of vias) may connect the ADC with the corresponding SRAM cell(s). For example, SRAM cell 334 may be connected to ADC 324 via a uTSV 304. During a frame capture by photodiodes 312, quantized pixel values may be transmitted from the ADC to third layer 330 for storage in SRAM 332 via the dedicated uTSVs. Depending on the operating frequency of the uTSVs, a single uTSV channel may be multiplexed (e.g., time-multiplexed) to transfer different data bits from the pixels of the DPS. For example, a single uTSV channel may have its time divided into four intervals and may send different types of data and/or data from different pixels in each of the four intervals. In some embodiments, third layer 330 may be implemented on smaller-density silicon (e.g., <22 nm), which may thereby allow for a smaller form factor.

In some embodiments, a stacked camera-image-sensor circuit may be designed to optimize the parameters of uTSVs, including higher density, smaller size, driver circuit control, available communication protocols, etc. Such optimizations may enable tight three-dimensional (3D) integrated circuit (IC) integration of a processor or other element on one layer of the system with elements on other layers of the system.

FIG. 4 illustrates a diagram of transferring data from a second layer to a third layer of a digital pixel sensor system (e.g., a multi-layer integrated circuit). Leveraging uTSVs for data transfer may incur area overhead on the second and third layers, as each uTSV will take up some area on the second and third layers of the integrated circuit. The embodiments herein may be configured to determine an optimum number of uTSVs to implement in a given DPS system. In some cases, the optimal number of uTSVs may depend on the processing bandwidth of the hardware processors on a given layer. Additionally or alternatively, other characteristics may affect the optimal number of uTSVs including image capture frequency, data transmission frequency, encoder output, and other characteristics. Thus, simply adding a large number of uTSVs to the DPS system and placing the uTSVs as densely as possible between the second and third layers (or the third and fourth layers, etc.) may not be optimal in all situations.

Accordingly, the embodiments herein may be configured to divide the digital pixel array of the first layer into multiple blocks and then pack the image data of each block together for transfer. For instance, a pixel array 401 may be divided into multiple blocks and fed to an encoder 402. The digital data may then be shared across one or more uTSV channels 403 using time multiplexing or some other type of multiplexing or other transmission method that may speed up the transfer. In some cases, the data may be encoded prior to transfer and, at least in some cases, the data may be compressed prior to transfer using various compression algorithms. On the third layer, the data may be unencoded by decoder 404 (and/or uncompressed, if applicable), resulting in decoded pixel data 405. This decoded pixel data may then be used by the processing hardware to identify objects, to track objects, or to perform other types of processing on an image or set of images.

In some cases, different numbers of uTSVs may be modeled using a specific number of photodiode inputs and/or a specific number of processor outputs. Using such modeling, the optimal number of uTSVs may be identified such that the area taken up by uTSV junctures on the relevant layers is not so high that it impedes the amount of processing that can be performed by the processing hardware, but is large enough to provide bandwidth sufficient to transfer the available pixel data from the digital pixel sensors. Such simulation may also take into account any multiplexing, encoding, compression, etc. to arrive at an optimal block granularity that is specific to each DPS device, according to its photodiode detectors, image processing hardware, and/or machine learning processing hardware.

As described above, the stacked camera-image-sensor circuit described herein may have a smaller form factor and/or operate more efficiently due to splitting up the ADCs and SRAM onto two separate layers. In some embodiments, additional components (e.g., processing hardware) may each be isolated onto their own layer. By connecting different layers with uTSVs, the systems described herein may save chip space, reducing the overall size and improving the efficiency of the sensor compared to designs that use TSVs. In some embodiments, the uTSVs may allow for data to be sent from the ADCs to the memory in a highly efficient manner that allows the ADCs and the memory cells to operate at maximal speed.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 500 in FIG. 5) or that visually immerses a user in an artificial reality (such as, e.g., virtual-reality system 600 in FIG. 6). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 5, augmented-reality system 500 may include an eyewear device 502 with a frame 510 configured to hold a left display device 515(A) and a right display device 515(B) in front of a user's eyes. Display devices 515(A) and 515(B) may act together or independently to present an image or series of images to a user. While augmented-reality system 500 includes two displays, embodiments of this disclosure may be implemented in augmented-reality systems with a single NED or more than two NEDs.

In some embodiments, augmented-reality system 500 may include one or more sensors, such as sensor 540. Sensor 540 may generate measurement signals in response to motion of augmented-reality system 500 and may be located on substantially any portion of frame 510. Sensor 540 may represent one or more of a variety of different sensing mechanisms, such as a position sensor, an inertial measurement unit (IMU), a depth camera assembly, a structured light emitter and/or detector, or any combination thereof. In some embodiments, augmented-reality system 500 may or may not include sensor 540 or may include more than one sensor. In embodiments in which sensor 540 includes an IMU, the IMU may generate calibration data based on measurement signals from sensor 540. Examples of sensor 540 may include, without limitation, accelerometers, gyroscopes, magnetometers, other suitable types of sensors that detect motion, sensors used for error correction of the IMU, or some combination thereof.

In some examples, augmented-reality system 500 may also include a microphone array with a plurality of acoustic transducers 520(A)-520(J), referred to collectively as acoustic transducers 520. Acoustic transducers 520 may represent transducers that detect air pressure variations induced by sound waves. Each acoustic transducer 520 may be configured to detect sound and convert the detected sound into an electronic format (e.g., an analog or digital format). The microphone array in FIG. 5 may include, for example, ten acoustic transducers: 520(A) and 520(B), which may be designed to be placed inside a corresponding ear of the user, acoustic transducers 520(C), 520(D), 520(E), 520(F), 520(G), and 520(H), which may be positioned at various locations on frame 510, and/or acoustic transducers 520(1) and 520(J), which may be positioned on a corresponding neckband 505.

In some embodiments, one or more of acoustic transducers 520(A)-(J) may be used as output transducers (e.g., speakers). For example, acoustic transducers 520(A) and/or 520(B) may be earbuds or any other suitable type of headphone or speaker.

The configuration of acoustic transducers 520 of the microphone array may vary. While augmented-reality system 500 is shown in FIG. 5 as having ten acoustic transducers 520, the number of acoustic transducers 520 may be greater or less than ten. In some embodiments, using higher numbers of acoustic transducers 520 may increase the amount of audio information collected and/or the sensitivity and accuracy of the audio information. In contrast, using a lower number of acoustic transducers 520 may decrease the computing power required by an associated controller 550 to process the collected audio information. In addition, the position of each acoustic transducer 520 of the microphone array may vary. For example, the position of an acoustic transducer 520 may include a defined position on the user, a defined coordinate on frame 510, an orientation associated with each acoustic transducer 520, or some combination thereof.

Acoustic transducers 520(A) and 520(B) may be positioned on different parts of the user's ear, such as behind the pinna, behind the tragus, and/or within the auricle or fossa. Or, there may be additional acoustic transducers 520 on or surrounding the ear in addition to acoustic transducers 520 inside the ear canal. Having an acoustic transducer 520 positioned next to an ear canal of a user may enable the microphone array to collect information on how sounds arrive at the ear canal. By positioning at least two of acoustic transducers 520 on either side of a user's head (e.g., as binaural microphones), augmented-reality system 500 may simulate binaural hearing and capture a 3D stereo sound field around about a user's head. In some embodiments, acoustic transducers 520(A) and 520(B) may be connected to augmented-reality system 500 via a wired connection 530, and in other embodiments acoustic transducers 520(A) and 520(B) may be connected to augmented-reality system 500 via a wireless connection (e.g., a BLUETOOTH connection). In still other embodiments, acoustic transducers 520(A) and 520(B) may not be used at all in conjunction with augmented-reality system 500.

Acoustic transducers 520 on frame 510 may be positioned in a variety of different ways, including along the length of the temples, across the bridge, above or below display devices 515(A) and 515(B), or some combination thereof. Acoustic transducers 520 may also be oriented such that the microphone array is able to detect sounds in a wide range of directions surrounding the user wearing the augmented-reality system 500. In some embodiments, an optimization process may be performed during manufacturing of augmented-reality system 500 to determine relative positioning of each acoustic transducer 520 in the microphone array.

In some examples, augmented-reality system 500 may include or be connected to an external device (e.g., a paired device), such as neckband 505. Neckband 505 generally represents any type or form of paired device. Thus, the following discussion of neckband 505 may also apply to various other paired devices, such as charging cases, smart watches, smart phones, wrist bands, other wearable devices, hand-held controllers, tablet computers, laptop computers, other external compute devices, etc.

As shown, neckband 505 may be coupled to eyewear device 502 via one or more connectors. The connectors may be wired or wireless and may include electrical and/or non-electrical (e.g., structural) components. In some cases, eyewear device 502 and neckband 505 may operate independently without any wired or wireless connection between them. While FIG. 5 illustrates the components of eyewear device 502 and neckband 505 in example locations on eyewear device 502 and neckband 505, the components may be located elsewhere and/or distributed differently on eyewear device 502 and/or neckband 505. In some embodiments, the components of eyewear device 502 and neckband 505 may be located on one or more additional peripheral devices paired with eyewear device 502, neckband 505, or some combination thereof.

Pairing external devices, such as neckband 505, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 500 may be provided by a paired device or shared between a paired device and an eyewear device, thus reducing the weight, heat profile, and form factor of the eyewear device overall while still retaining desired functionality. For example, neckband 505 may allow components that would otherwise be included on an eyewear device to be included in neckband 505 since users may tolerate a heavier weight load on their shoulders than they would tolerate on their heads. Neckband 505 may also have a larger surface area over which to diffuse and disperse heat to the ambient environment. Thus, neckband 505 may allow for greater battery and computation capacity than might otherwise have been possible on a standalone eyewear device. Since weight carried in neckband 505 may be less invasive to a user than weight carried in eyewear device 502, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 505 may be communicatively coupled with eyewear device 502 and/or to other devices. These other devices may provide certain functions (e.g., tracking, localizing, depth mapping, processing, storage, etc.) to augmented-reality system 500. In the embodiment of FIG. 5, neckband 505 may include two acoustic transducers (e.g., 520(1) and 520(J)) that are part of the microphone array (or potentially form their own microphone subarray). Neckband 505 may also include a controller 525 and a power source 535.

Acoustic transducers 520(1) and 520(J) of neckband 505 may be configured to detect sound and convert the detected sound into an electronic format (analog or digital). In the embodiment of FIG. 5, acoustic transducers 520(1) and 520(J) may be positioned on neckband 505, thereby increasing the distance between the neckband acoustic transducers 520(1) and 520(J) and other acoustic transducers 520 positioned on eyewear device 502. In some cases, increasing the distance between acoustic transducers 520 of the microphone array may improve the accuracy of beamforming performed via the microphone array. For example, if a sound is detected by acoustic transducers 520(C) and 520(D) and the distance between acoustic transducers 520(C) and 520(D) is greater than, e.g., the distance between acoustic transducers 520(D) and 520(E), the determined source location of the detected sound may be more accurate than if the sound had been detected by acoustic transducers 520(D) and 520(E).

Controller 525 of neckband 505 may process information generated by the sensors on neckband 505 and/or augmented-reality system 500. For example, controller 525 may process information from the microphone array that describes sounds detected by the microphone array. For each detected sound, controller 525 may perform a direction-of-arrival (DOA) estimation to estimate a direction from which the detected sound arrived at the microphone array. As the microphone array detects sounds, controller 525 may populate an audio data set with the information. In embodiments in which augmented-reality system 500 includes an inertial measurement unit, controller 525 may compute all inertial and spatial calculations from the IMU located on eyewear device 502. A connector may convey information between augmented-reality system 500 and neckband 505 and between augmented-reality system 500 and controller 525. The information may be in the form of optical data, electrical data, wireless data, or any other transmittable data form. Moving the processing of information generated by augmented-reality system 500 to neckband 505 may reduce weight and heat in eyewear device 502, making it more comfortable for the user.

Power source 535 in neckband 505 may provide power to eyewear device 502 and/or to neckband 505. Power source 535 may include, without limitation, lithium ion batteries, lithium-polymer batteries, primary lithium batteries, alkaline batteries, or any other form of power storage. In some cases, power source 535 may be a wired power source. Including power source 535 on neckband 505 instead of on eyewear device 502 may help better distribute the weight and heat generated by power source 535.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 600 in FIG. 6, that mostly or completely covers a user's field of view. Virtual-reality system 600 may include a front rigid body 602 and a band 604 shaped to fit around a user's head. Virtual-reality system 600 may also include output audio transducers 606(A) and 606(B). Furthermore, while not shown in FIG. 6, front rigid body 602 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 500 and/or virtual-reality system 600 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 500 and/or virtual-reality system 600 may include microLED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 500 and/or virtual-reality system 600 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, bodysuits, handheld controllers, environmental devices (e.g., chairs, floor mats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

### EXAMPLE EMBODIMENTS

Example 1: A stacked camera-image-sensor circuit may include a first layer that includes a plurality of image sensing elements, a second layer that includes components that interface with the image sensing elements, and at least one additional layer that includes image-processing components.

Example 2: The stacked camera-image-sensor circuit of example 1, where the at least one additional layer including image-processing components includes a plurality of additional layers and each layer within the plurality of additional layers includes at least one specialized component not found on any other layer within the plurality.

Example 3: The stacked camera-image-sensor circuit of examples 1-2, where the plurality of image sensing elements include photodiodes.

Example 4: The stacked camera-image-sensor circuit of examples 1-3, where the components that interface with the image sensing elements include a plurality of ADCs and the at least one additional layer includes a plurality of memory cells, where the ADCs are communicatively connected to the memory cells through one or more vias.

Example 5: The stacked camera-image-sensor circuit of examples 1-4, where the memory cells include SRAM cells.

Example 6: The stacked camera-image-sensor circuit of examples 1-5, where the one or more vias include uTSVs.

Example 7: The stacked camera-image-sensor circuit of examples 1-6, where data from the ADCs is multiplexed through the uTSVs to the memory cells.

Example 8: A method may include (i) capturing, by an image sensing element embedded in a first layer of a stacked camera-image-sensor circuit, visual data, (ii) receiving, by a component in a second layer of the stacked camera-image-sensor circuit, the visual data from the image sensing component, and (iii) processing, by an image-processing component in a third layer of the stacked camera-image-sensor circuit, the visual data received by the component in the second layer.

Example 9: The method of example 8 may further include processing the visual data by a plurality of additional image-processing components includes housed within a plurality of additional layers of the stacked camera-image-sensor circuit such that each layer within the plurality of additional layers houses at least one specialized image-processing component not found on any other layer within the plurality.

Example 10: The method of examples 8-9, where the image sensing element includes a photodiode.

Example 11: The method of examples 8-10, where the component in the second layer includes a plurality of ADCs and the third layer includes a plurality of memory cells, where the ADCs are communicatively connected to the memory cells through one or more vias.

Example 12: The method of examples 8-11, where the memory cells include SRAM cells.

Example 13: The method of examples 8-12, where the one or more vias include uTSVs.

Example 14: The method of examples 8-13, where processing, by the image-processing component in the third layer of the stacked camera-image-sensor circuit, the visual data received by the component in the second layer includes multiplexing the visual data from the ADCs through the uTSVs to the memory cells.

Example 15: A method may include assembling a stacked camera-image-sensor circuit by connecting (i) a first layer including a plurality of image sensing elements, (ii) a second layer including components that interface with the image sensing elements, and (iii) at least one additional layer including image-processing components.

Example 16: The method of example 15, where the at least one additional layer including image-processing components includes a plurality of additional layers and each layer within the plurality of additional layers includes at least one specialized component not found on any other layer within the plurality.

Example 17: The method of examples 15-16, where the plurality of image sensing elements include photodiodes.

Example 18: The method of examples 15-17, where the components that interface with the image sensing elements include a plurality of ADCs and the at least one additional layer includes a plurality of memory cells, where the ADCs are communicatively connected to the memory cells through one or more vias.

Example 19: The method of examples 15-18, where the memory cells include SRAM cells.

Example 20: The method of examples 15-19, where the one or more vias include uTSVs.

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. For example, one or more of the modules recited herein may receive image data to be transformed, transform the image data into a data structure that stores user characteristic data, output a result of the transformation to select a customized interactive ice breaker widget relevant to the user, use the result of the transformation to present the widget to the user, and store the result of the transformation to create a record of the presented widget. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

In some embodiments, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A stacked camera-image-sensor circuit comprising:
a first layer comprising a plurality of image sensing elements;
a second layer comprising components that interface with the image sensing elements; and
at least one additional layer comprising image-processing components.

2. The stacked camera-image-sensor circuit of claim 1, wherein:
the at least one additional layer comprising image-processing components comprises a plurality of additional layers; and
each layer within the plurality of additional layers comprises at least one specialized component not found on any other layer within the plurality.

3. The stacked camera-image-sensor circuit of claim 1, wherein the plurality of image sensing elements comprise photodiodes.

4. The stacked camera-image-sensor circuit of claim 1, wherein:
the components that interface with the image sensing elements comprise a plurality of analog-to-digital converters (ADCs); and
the at least one additional layer comprises a plurality of memory cells, wherein the ADCs are communicatively connected to the memory cells through one or more vias.

5. The stacked camera-image-sensor circuit of claim 4, wherein the memory cells comprise static random access memory (SRAM) cells.

6. The stacked camera-image-sensor circuit of claim 4, wherein the one or more vias comprise micro through-silicon vias (uTSVs).

7. The stacked camera-image-sensor circuit of claim 6, wherein data from the ADCs is multiplexed through the uTSVs to the memory cells.

8. A method comprising:
capturing, by an image sensing element embedded in a first layer of a stacked camera-image-sensor circuit, visual data;
receiving, by a component in a second layer of the stacked camera-image-sensor circuit, the visual data from the image sensing component; and
processing, by an image-processing component in a third layer of the stacked camera-image-sensor circuit, the visual data received by the component in the second layer.

9. The method of claim 8, further comprising processing the visual data by a plurality of additional image-processing components comprises housed within a plurality of additional layers of the stacked camera-image-sensor circuit such that each layer within the plurality of additional layers houses at least one specialized image-processing component not found on any other layer within the plurality.

10. The method of claim 8, wherein the image sensing element comprises a photodiode.

11. The method of claim 8, wherein:
the component in the second layer comprises a plurality of ADCs; and
the third layer comprises a plurality of memory cells, wherein the ADCs are communicatively connected to the memory cells through one or more vias.

12. The method of claim 11, wherein the memory cells comprise SRAM cells.

13. The method of claim 11, wherein the one or more vias comprise uTSVs.

14. The method of claim 13, wherein processing, by the image-processing component in the third layer of the stacked camera-image-sensor circuit, the visual data received by the component in the second layer comprises multiplexing the visual data from the ADCs through the uTSVs to the memory cells.

15. A method comprising:
assembling a stacked camera-image-sensor circuit by connecting:
a first layer comprising a plurality of image sensing elements;
a second layer comprising components that interface with the image sensing elements; and
at least one additional layer comprising image-processing components.

16. The method of claim 15, wherein:
the at least one additional layer comprising image-processing components comprises a plurality of additional layers; and
each layer within the plurality of additional layers comprises at least one specialized component not found on any other layer within the plurality.

17. The method of claim 15, wherein the plurality of image sensing elements comprise photodiodes.

18. The method of claim 15, wherein:
the components that interface with the image sensing elements comprise a plurality of ADCs; and
the at least one additional layer comprises a plurality of memory cells, wherein the ADCs are communicatively connected to the memory cells through one or more vias.

19. The method of claim 18, wherein the memory cells comprise SRAM cells.

20. The method of claim 18, wherein the one or more vias comprise uTSVs.
